(19) United States
(12) Patent Application Publication
(10) Pub. No.: US 2023/0297050 A1
(43) Pub. Date: Sep. 21, 2023

(54) HUMAN-COMPUTER INTERACTION SYSTEM AND METHOD BASED ON WIRELESS CHARGING DEVICE

(71) Applicant: TIANJIN UNIVERSITY, Tianjin (CN)

(72) Inventors: Xiulong Liu, Tianjin (CN); Keqiu Li, Tianjin (CN); Yuesen Liu, Tianjin (CN); Jiuwu Zhang, Tianjin (CN); Xin Xie, Tianjin (CN)

(21) Appl. No.: 17/982,900

(22) Filed: Nov. 8, 2022

(30) Foreign Application Priority Data
Mar. 21, 2022 (CN) 2022102810652

(51) Int. Cl. G05B 19/042; H02J 50/10; H02J 50/40; H02J 50/80; H02J 50/90; H02J 7/00; G01R 21/00

(52) U.S. Cl. CPC G05B 19/042; H02J 50/10; H02J 50/402; H02J 50/80; H02J 50/90; H02J 7/0047; G01R 21/00; G05B 2219/2642; H04L 12/282

(57) ABSTRACT

A human-computer interaction system and method based on a wireless charging device are provided. The system includes: a multi-coil wireless charging circuit, including wireless charging coils arranged in a 3*3 matrix; a power information collection circuit, configured to acquire power data of each of at least two wireless charging coils of the wireless charging coils when the wireless charging device slides through the at least two wireless charging coils; a data processing circuit, configured to generate a motion trajectory of the wireless charging device based on the power data of each of the at least two wireless charging coils, and identify a user instruction corresponding to the motion trajectory using a preset instruction identification model, the instruction identification model being a neural network model based on deep supervised learning; and a cloud server, configured to control a smart home device based on the user instruction.

### TECHNICAL FIELD

The present relates to the field of human-computer interaction, and in particularly, to a human-computer interaction system based on a wireless charging device and a human-computer interaction method based on a wireless charging device using the system.

### DESCRIPTION OF RELATED ART

With the development of the internet of things and smart home devices, an application of smart internet of things devices is becoming more and more extensive, and the smart home devices are also deepening into all aspects of industry and life. Nowadays, more and more people use the smart home devices to replace traditional homes in their family. The smart home devices bring great convenience to our lives and greatly improves our quality of life.

With the increase of the smart home devices, how to conveniently and efficiently control the smart home devices has gradually become a problem that people pay attention to. For a current smart home, there are few types of human-computer interaction devices used to control the smart home devices, which are mainly a smart speaker and a smart phone. However, whether using the smart speaker or using the smart phone in the process of human-computer interaction, one smart home device is required to be occupied, as such, an operation during using the one smart home device is inconvenient and the one smart home device cannot be used to the greatest extent.

### SUMMARY

In view of the above problems existed in the related art, embodiments of the present disclosure provides a human-computer interaction system based on a wireless charging device and a human-computer interaction method based on a wireless charging device using the system, in which a motion trajectory of the wireless charging device is generated based on power data obtained when the wireless charging device slides through multi-coil wireless charging circuit, a user instruction is identified based the motion trajectory, to control a smart home device, the multi-coil wireless charging circuit is fully utilized, which solves the problem that a special smart home device is required to be occupied during a process of human-computer interaction.

A first aspect of the embodiments of the present disclosure provides a human-computer interaction system based on a wireless charging device, which includes: a multi-coil wireless charging circuit, including wireless charging coils arranged in a 3*3 matrix; a power information collection circuit, configured to acquire power data of each of at least two wireless charging coils of the wireless charging coils of the multi-coil wireless charging circuit when the wireless charging device slides through the at least two wireless charging coils; a data processing circuit, configured to generate a motion trajectory of the wireless charging device based on the power data of each of the at least two wireless charging coils, and identify a user instruction corresponding to the motion trajectory of the wireless charging device using a preset instruction identification model, the instruction identification model being a neural network model based on deep supervised learning; and a cloud server, configured to control a smart home device based on the user instruction.

In a preferable embodiment of the embodiment, the power information collection circuit includes a data acquisition sub-circuit, and the data acquisition sub-circuit includes a power sensor and a clock timer and is configured to acquire the power data of each of the at least two wireless charging coils of the wireless charging coils of the multi-coil wireless charging circuit when the wireless charging device slides through the at least two wireless charging coils, and the power data of each of the at least two wireless charging coils includes a coil number, current change amplitudes, and a current change time.

In a preferable embodiment of the embodiment, the power information collection circuit further includes a data transmission sub-circuit, the data transmission sub-circuit is connected in communication with the data processing circuit, and configured to transmit the power data of the at least two wireless charging coils to the data processing circuit.

In a preferable embodiment of the embodiment, the data processing circuit includes a data processing sub-circuit and an instruction identification sub-circuit; the data processing sub-circuit is electrically connected to the instruction identification sub-circuit; and the data processing sub-circuit is configured to generate the motion trajectory of the wireless charging device based on the power data of the at least two wireless charging coils, and transmit the motion trajectory to the instruction identification sub-circuit; and the instruction identification sub-circuit is connected in communication with the cloud server, and is configured to load the preset instruction identification model to identify the user instruction corresponding to the motion trajectory, and transmit the user instruction to the cloud server.

A second aspect of the embodiments of the present disclosure provides a human-computer interaction method based on a wireless charging device using the above system, and the method includes: starting the multi-coil wireless charging circuit; obtaining the power data of each of at least two wireless charging coils of the wireless charging coils of the multi-coil wireless charging circuit when the wireless charging device slides through the at least two wireless charging coils; generating the motion trajectory of the wireless charging device based on the power data of the at least two wireless charging coils, and identifying the user instruction corresponding to the motion trajectory of the wireless charging device using the preset instruction identification model, the instruction identification model being the neural network model based on deep supervised learning; and controlling the smart home device based on the user instruction.

In a preferable embodiment of the embodiment, the generating the motion trajectory of the wireless charging device based on the power data of the at least two wireless charging coils, specifically includes: step S1, obtaining the power data of the at least two wireless charging coils, and screening the power data of the at least two wireless charging coils to obtain a set of accurate power data; step S2, obtaining a coil number of each power data of the set of accurate power data, and ordering obtained coil numbers in time sequence, to obtain a wireless charging coil number sequence; and step S3, connecting wireless charging coils of the multi-coil wireless charging circuit corresponding to the obtained coil numbers based on the wireless charging coil number sequence, to obtain a wireless charging coil connecting line as the motion trajectory of the wireless charging device.

In a preferable embodiment of the embodiment, the screening the power data of the at least two wireless charging coils to obtain a set of accurate power data in the step S1, specifically includes: obtaining a maximum value of current change amplitudes and a current change time of the power data of each of the at least two wireless charging coils; determining a power data screening value of the power data of each of the at least two wireless charging coils based on the maximum value of the current change amplitudes and the current change time; and determining whether the power data screening value is within a set threshold range, if it is determined that the power data screening value is within the set threshold range, obtaining the power data as accurate power data of the set of accurate power data, otherwise not making the power data as accurate power data of the set of accurate power data.

In a preferable embodiment of the embodiment of the present disclosure, the power data screening value is determined by a following formula: Sᵢ=max[Eᵢ]*Tᵢ, where Sᵢ represent the power data screening value of the i-th wireless charging coil of the wireless charging coils, max[Eᵢ] represents the maximum value of the current change amplitudes of the i-th wireless charging coil, and Tᵢ represents the current change time of the i-th wireless charging coil.

The human-computer interaction system and method based on the wireless charging device of the present disclosure have at least the following beneficial effects.
1. In the embodiments of the present disclosure, during the process of the human-computer interaction, the wireless charging coils on the wireless charging circuit board are cut by the wireless charging device, the power data is generated, and the motion trajectory is generated, and the user instruction is further identified to control the smart home device. The whole process will not interfere with a normal operation of the wireless charging circuit board, and thus the wireless charging circuit board is fully utilized. It is not required to occupy a special smart home device, and the implementation cost therefor is low.
2. In the embodiments of the present disclosure, since the motion trajectory of the wireless charging device is identified through a trained neural network model based on deep supervised learning, to output the corresponding user instruction, the identification accuracy is high. Since the trained identification model is used, the data processing process in the human-computer interaction process is simplified, thereby making the human-computer interaction more efficient.
3. The embodiments of the present disclosure innovatively proposes a manner for controlling the smart home device through the wireless charging circuit board, thereby increasing the optional type of human-computer interaction device for controlling the smart home device.

### BRIEF DESCRIPTION OF THE DRAWINGS

In order to illustrate technical solutions of embodiments of the present disclosure more clearly, accompanying drawings required to be used in the embodiments are introduced briefly hereinafter. It is apparent that the accompanying drawings in the following description are merely some embodiments of the present disclosure, other drawings can also be obtained from these drawings without any creative effort for those of ordinary skill in the art.

FIG. 1 illustrates an overall frame view of a human-computer interaction system based on a wireless charging device according to an embodiment of the present disclosure.

FIG. 2 illustrates a flow chart showing a process for generating a motion trajectory of a wireless charging device according to an embodiment of the present disclosure.

FIG. 3 illustrates a schematic view of an operation process according to an embodiment of the present disclosure.

FIG. 4 is a comparative schematic view of operation processes a and b according to an embodiment of the present disclosure.

### DETAILED DESCRIPTION OF EMBODIMENTS

In the following description, for the purpose of illustration rather than limitation, specific details such as specific system structures and technologies are set forth in order to provide a thorough understanding of the embodiments of the present disclosure. However, it should be understood for those skilled in the art that the present disclosure may be achieved in other embodiments without these specific details. In some instances, detailed descriptions of well-known systems, devices, circuits, and methods are omitted, so as to prevent unnecessary detail from obscuring the description of the present disclosure.

An embodiment of the present disclosure provides a human-computer interaction system based on a wireless charging device, and the system includes:
a multi-coil wireless charging circuit, including wireless charging coils arranged in a 3×3 matrix;
a power information collection circuit, configured to collect power data of each of at least two wireless charging coils of the wireless charging coils of the multi-coil wireless charging circuit when the wireless charging device slides through the at least two wireless charging coils;
a data processing circuit, configured to generate a motion trajectory of the wireless charging device based on the power data of each of the at least two wireless charging coils, and identify a user instruction corresponding to the motion trajectory of the wireless charging device using a preset instruction identification model, the instruction identification model being a neural network model based on deep supervised learning; and
a cloud server, configured control one or more smart home devices connected to the cloud server based on the user instruction.

In the above system, the power information collection circuit may include a data acquisition sub-circuit, and the data acquisition sub-circuit includes a power sensor and a clock timer, and configured to acquire the power data of each of the at least two wireless charging coils of the wireless charging coils of the multi-coil wireless charging circuit when the wireless charging device slides through the at least two wireless charging coils. The power data of each of the at least two wireless charging coils includes a coil number, current change amplitudes, and a current change time.

In the above system, the power information collection circuit may further include a data transmission sub-circuit. The data transmission sub-circuit is connected in communication with the data processing circuit, and is configured to transmit the power data to the data processing circuit.

In the above system, the data processing circuit may include a data processing sub-circuit and an instruction identification sub-circuit.

The data processing sub-circuit is electrically connected to the instruction identification sub-circuit, and is configured to generate the motion trajectory of the wireless charging device based on the power data of the at least two wireless charging coils, and transmit the motion trajectory to the instruction identification sub-circuit.

The instruction identification sub-circuit is connected in communication with the cloud server, and is configured to load the preset instruction identification model to identify the user instruction corresponding to the motion trajectory, and transmit the user instruction to the cloud server.

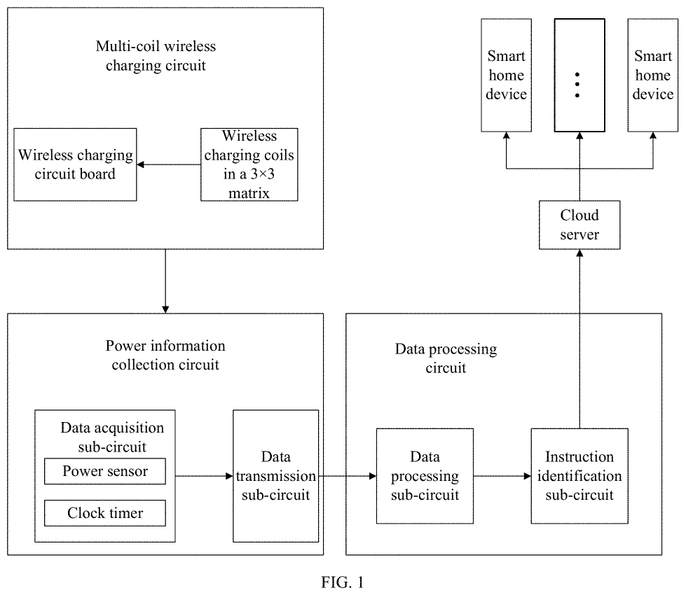

Referring to FIG. 1, in an embodiment of the present disclosure, a multi-coil wireless charging circuit preferably includes wireless charging coils arranged in a 3×3 matrix. The wireless charging coils are electrically connected to a wireless charging circuit board. After the wireless charging circuit board is started, the multi-coil wireless charging circuit is powered on and started, and the wireless charging coils generate an electromagnetic field. In this case, if a wireless charging device slides through a surface of the multi-coil wireless charging circuit, a coil in the wireless charging device will cut the electromagnetic field generated by corresponding wireless charging coils (which are overlapped by the wireless charging device), such that a current is generated, and a current data of the corresponding wireless charging coils changes.

The multi-coil wireless charging circuit and a power information collection circuit are connected to one another. The power information collection circuit includes a data acquisition sub-circuit. The data acquisition sub-circuit preferably includes a power sensor and a clock timer. The power information collection circuit monitors the current data of the wireless charging coils in real time through the power sensor. When the current data of each of the wireless charging coils changes, the power information collection circuit will acquire a change data of the current data of the wireless charging coil, and record a coil number of the wireless charging coil, current change amplitudes of the wireless charging coil, and a current change time of the wireless charging coil as the power data of the wireless charging coil, and then send the recorded power data to a data processing circuit through a data transmission sub-circuit.

After the data processing circuit receives the power data, the data processing circuit may analyze the power data and generate the motion trajectory of the wireless charging device during the wireless charging device sliding onto the surface of the multi-coil wireless charging circuit, and then input the generated motion trajectory into a preset instruction identification model to identify a user instruction corresponding to the motion trajectory of the wireless charging device, where the instruction identification model is a neural network model based on deep supervised learning. The data processing circuit will send the identified user instruction to a cloud server, and the cloud server can control a smart home device through the user instruction.

It should be noted that, in some embodiments, the data processing circuit, the data processing sub-circuit and the instruction identification sub-circuit described above may be implemented/embodied by one or more memories stored software modules therein and one or more processors coupled to the one or more memories and configured to execute the software modules. Further, the data transmission sub-circuit may be for example a data transmission interface, but which is not limited thereto, it can be other form, as long as it can implement the corresponding function.

Through this system, the smart home device is controlled through human-computer interaction. During the process of the human-computer interaction, the wireless charging coils on the wireless charging circuit board are cut by the wireless charging device, the power data is generated, and the motion trajectory is generated, and the user instruction is further identified. The whole process will not interfere with a normal operation of the wireless charging circuit board. It is not required to occupy a special smart home device during the process of the human-computer interaction, and the wireless charging circuit board is fully utilized. Further, since the user instruction is identified through the neural network model based on deep supervised learning, identification accuracy is high. Moreover, the process of the human-computer interaction is simple, and the operation therefor is convenient. Therefore, a novel manner of human-computer interaction for controlling smart home devices is provided.

In the above system, in an embodiment of the present disclosure, the generating the motion trajectory of the wireless charging device based on the power data of the at least two wireless charging coils may include the following steps S1 to S3.

In step S1, the power data of the at least two wireless charging coils is obtained, and the power data of the at least two wireless charging coils is screened to obtain a set of accurate power data.

In step S2, a coil number of each power data of the set of accurate power data is acquired, and obtained coil numbers are ordered in time sequence to obtain a wireless charging coil number sequence.

In step S3, wireless charging coils of the multi-coil wireless charging circuit corresponding to the obtained coil numbers based on the wireless charging coil number sequence are connected, so as to obtain a wireless charging coil connecting line as the motion trajectory of the wireless charging device.

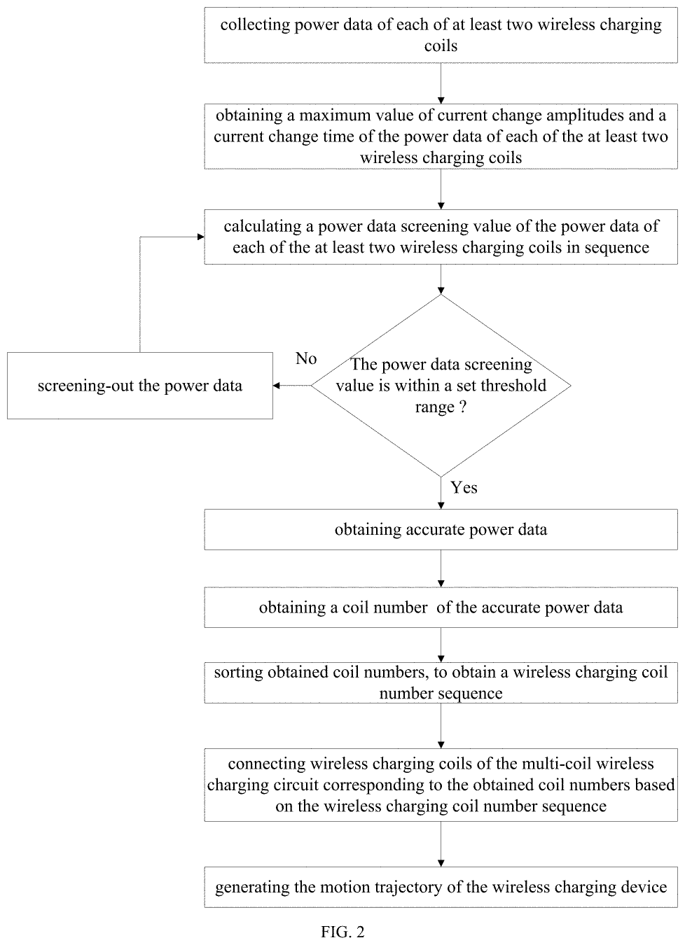

Referring to FIG. 2, in this embodiment of the present disclosure, the motion trajectory of the wireless charging device is generated based on the power data of the at least two wireless charging coils, so that the power data of the at least two wireless charging coils is converted into the specific motion trajectory, such that a data feature is added and it is facilitate to perform subsequent identification through the instruction identification model. Specifically, the power data of each of the at least two wireless charging coils is obtained and screened to obtain a set of accurate power data. In a case that the wireless charging device slides through the multi-coil wireless charging circuit, owing to affection of a volume and a slide angle of the wireless charging device, when the wireless charging device passes through one wireless charging coil of the wireless charging coils, an adjacent wireless charging coil to the one wireless charging coil may also generate power data. Therefore, it is required to screen the obtained power data to ensure the accuracy of the subsequently generated motion trajectory and make the human-computer interaction result more accurate.

Further, the coil numbers of the accurate power data obtained by screening according to the time sequence are ordered to obtain the wireless charging coil number sequence, i.e., a sequence of the wireless charging coils corresponding to the motion trajectory of the wireless charging device. For example, if the wireless charging coil number sequence is 1-2-3, it means that the wireless charging device starts to move from a No. 1 wireless charging coil, passes through a No. 2 wireless charging coil, and move to a No. 3 wireless charging coil and stops. Therefore, in the multi-coil charging circuit, the wireless charging coils are connected according to the wireless charging coil number sequence 1-2-3, to obtain a wireless charging coil connecting line as the motion trajectory of the wireless charging device.

In the above system, the screening the power data of the at least two wireless charging coils to obtain a set of accurate power data in the step Si may include:
obtaining a maximum value of current change amplitudes and a current change time of the power data of each of the at least two wireless charging coils;
determining a power data screening value of the power data of each of the at least two wireless charging coils based on the maximum value of the current change amplitudes and the current change time; and
determining whether the power data screening value is within a set threshold range, if it is determined that the power data screening value is within the set threshold range, obtaining the power data as accurate power data of the set of accurate power data, otherwise not making the power data as accurate power data of the set of accurate power data.

The power data screening value can be determined by a following formula (1):

Sᵢ=max[Eᵢ]*Tᵢ (1)

Specifically, Sᵢ represents the power data screening value of the i-th wireless charging coil of the wireless charging coils, max[Eᵢ] represents the maximum value of the current change amplitudes of the i-th wireless charging coil, and Tᵢ represents the current change time of the i-th wireless charging coil.

Referring to FIG. 2, it should be noted that a formula for calculating the current generated by electromagnetic induction can be determined by a following formula (2):

E=BLV sin θ (2)

Specifically, E represents the current generated by electromagnetic induction, B represents an intensity of a magnetic field, L represents a length of a coil, V is a speed at which the coil passes through the magnetic field, and θ represents an angle between the coil and a magnetic induction line. In the embodiments of the present disclosure, the intensity of the magnetic field is determined by a powered-on wireless charging coil. During an operation process, a voltage of the wireless charging coil is not changed, so the intensity of the magnetic field is not changed; the length of the coil is a length of the coil of the wireless charging device, so the length of the coil is not changed; and the wireless charging deice is close to and slides on a surface of the wireless charging coil, the angle between the coil and the magnetic induction line is not changed. Therefore, in the embodiments of the present disclosure, the current generated by the electromagnetic induction is only related to the speed at which the coil passes through the magnetic field, and thus the current can be used to screen the power data.

Specifically, in the embodiments of the present disclosure, a distance that the wireless charging device slides through the wireless charging coil is a diameter R of the wireless charging coil, so the speed at which the wireless charging device slides through the wireless charging coil can be determined by the diameter R of the wireless charging coil and the current change time T. Combined with the formula (2), it can be obtained from a formula (3):

$$E = BL sin θ \cdot \frac{R}{T} . \qquad ( 3 )$$

From the formula (3), a formula (4) can be obtained, ET=BL sin θR (4). In the embodiments of the present disclosure, since a product of the current generated when the wireless charging device slides through the wireless charging coil and the current change time corresponding to the current is a constant value, the power data screening value can be obtained according to the current change amplitudes and the current change time of the power data, to achieve the screening of the power data.

It should also be noted that since the wireless charging coil has a circle center, a maximum current is reached when the wireless charging device passes through the circle center. Therefore, in the embodiments of the present disclosure, the power data screening value is obtained based on the maximum value of the current change amplitudes of the power data and the current change time (corresponding to the maximum value). Further, due to affection of the volume and the sliding angle of the wireless charging device, the power data screening value may not accurately reach a threshold. Therefore, when screening, as long as the power data screening value is within the set threshold range, the power data screening value can be considered as the accurate power data. The threshold range is preferably [0.8BL sinθR, 1.2BL sin θR].

An embodiment of the present disclosure provides a human-computer interaction method based on a wireless charging device, which includes:
starting multi-coil wireless charging circuit;
acquiring power data of each of at least two wireless charging coils of the wireless charging coils when the wireless charging device slides through the at least two wireless charging coils;
generating a motion trajectory of the wireless charging device based on the power data of the at least two wireless charging coils, and identifying the user instruction corresponding to the motion trajectory of the wireless charging device using the preset instruction identification model, the instruction identification model being the neural network model based on deep supervised learning; and
controlling a smart home device based on the user instruction.

In the embodiment of the present disclosure, the motion trajectory of the wireless device is generated by obtaining the power data of each of at least two wireless charging coils of the wireless charging coils of the multi-coil wireless charging circuit when the wireless charging device slides through the at least two wireless charging coils, and the user identification instruction is identified based on the generated motion trajectory, so as to realize the human Computer interactive control of the smart home device. The steps of generating the motion trajectory of the wireless charging device based on the power data of each of the wireless charging coils are the same as the above.

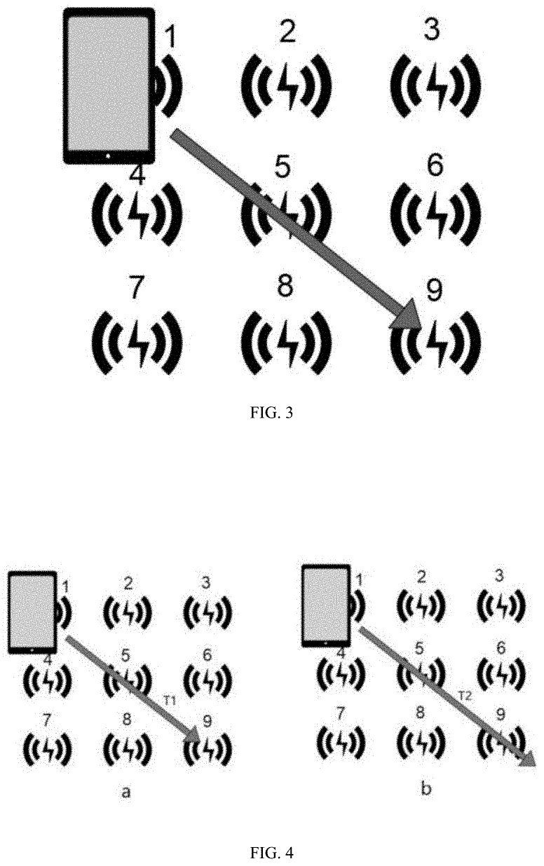

Specifically, for example, referring to FIG. 3, in the embodiment of the present disclosure, when a wireless charging device slides through wireless charging coils arranged in a 3*3 matrix on a surface of a wireless charging circuit board, the current of the wireless charging coils is changed, in this case, a power change of each wireless charging coil is monitored by a power information collection circuit, and thus the power data of each wireless charging coil can be obtained. However, due to the affection of the volume and the sliding angle of the wireless charging device, the finally acquired power data may have interference items. Specifically, if the wireless charging device slides through wireless charging coils in a direction of an arrow in FIG. 3, power data of each of No. 1, No. 2, No. 4, No. 5, No. 6, No. 8, and No. 9 wireless charging coils may eventually be acquired, so it is required to screen the obtained power data.

Further, it can be known from the formulas (2), (3) and (4) that in the embodiment of the embodiment, when the wireless charging device slides through each of the above wireless charging coils, i.e., No. 1, No. 2, No. 4, No. 5, No. 6, No. 8, and No. 9 wireless charging coils, a product of the generated current and the corresponding current change time is close to a constant value, so a power data screening value can be obtained according to the current change amplitudes and the current change time of the power data, a specific calculation formula is shown in the formula (1). After the power data screening value is obtained, the power data screening value is compared with a set threshold, to achieve the screening of the power data. In an actual operation, due to the existence of various errors, the power data screening value may not accurately reach a threshold. Therefore, in order to ensure the identification pass rate, in the embodiment, as long as the power data screening value is within a threshold range, the power data screening value can be considered to be an accurate power data. The set threshold range is preferably [0.8BL sin θR, 1.2BL sin θR].

In the embodiment of the present disclosure, after the power data of No. 1, No. 2, No. 4, No. 5, No. 6, No. 8, and No. 9 wireless charging coils are screened, the power data of No. 1, No. 5, and No. 9 wireless charging coils can be obtained as the accurate power data. An obtained time of each of the power data of the No. 1, No. 5, and No. 9 wireless charging coils can be obtained through the clock timer. Then the power data of No. 1, No. 5, and No. 9 wireless charging coils can be ordered as 1-5-9, and thus the motion trajectory of the wireless charging device can be obtained as passing through the No. 1 wireless charging coil, then passing through the No. 5 wireless charging coil, and finally passing through the No. 9 wireless charging coil, as shown by the arrow in FIG. 3. The motion trajectory is input into the preset instruction identification model to obtain a corresponding user instruction, thereby for controlling the smart home device and achieve a process of human-computer interaction. The process of human-computer interaction occupies a low resource, an operation therefor is simple, and the identification accuracy is high. A novel human-computer interaction manner for modern smart homes is provided.

In a preferred embodiment of the present disclosure, in order to expand a quantity of user instructions that can be provided by the human-computer interaction system, in the embodiment, the user instruction corresponding to the motion trajectory can be further refined by adding features of the wireless charging device.

For example, referring to FIG. 4, the motion trajectory of the wireless charging device is obtained first, and as shown in FIG. 4, the motion trajectory of the wireless charging device is an arrow pointing to the lower right, and then a user instruction can be identified based on the motion trajectory. If the user instruction corresponding to the motion trajectory is t light-turn-off, the light-turn-off instruction can be executed. However, in the case of many smart devices being used in life, more user instructions may be required. If only the feature, i.e., the motion trajectory of the wireless charging device is used for identification, it may not be able to meet the requirements, so another feature can be added for identification. For example, if a feature, a movement duration of the wireless charging device is added, the identification process of the user instruction is: first obtaining the movement trajectory of the wireless charging device as an arrow pointing to the lower right, identifying a user instruction of “turn off” based on the movement trajectory, and then determining an object of the user instruction of “turn off” based on the duration of the movement duration of the wireless charging device, such as “light-turn-off”, “air-conditioner-turn-off”, and on the like.

Referring to FIG. 4, the movement duration of the wireless charging device can be embodied as a length of the movement trajectory. For example, a movement duration T1 of the wireless charging device in a of FIG. 4 is less than a movement duration T2 of the wireless charging device in b of FIG. 4, then a length of the motion trajectory of the wireless charging device in b of FIG. 4 is greater than a length of the motion trajectory of the wireless charging device in a of FIG. 4. More specifically, the length of the motion trajectory is a product of ae motion duration T and a unit length. During the identification process, specific identification can be made through a section where the length of the motion trajectory is located. For example, if the motion trajectory of the wireless charging device points to the lower right. arrow, and the length of the motion trajectory is within an unit length section (0, 3], the corresponding user instruction is “light-turn-off”; if the motion trajectory of the wireless charging device is an arrow pointing to the lower right, and the length of the motion trajectory is within an unit length section (3,6], the corresponding user instruction is “air-conditioner-turn-off. This method can enable a user to complete more complex human-computer interaction operations to meet actual requirements of the user in daily life.

The present disclosure is not limited to the above-mentioned specific embodiments, and various transformations made by those of ordinary skill in the art based on the above-mentioned concept without a creative labor all fall within the protection scope of the present disclosure.

What is claimed is:

1. A human-computer interaction system based on a wireless charging device, comprising:
a multi-coil wireless charging circuit, comprising wireless charging coils arranged in a 3*3 matrix;
a power information collection circuit, configured to collect power data of each of at least two wireless charging coils of the wireless charging coils of the multi-coil wireless charging circuit when the wireless charging device slides through the at least two wireless charging coils;
a data processing circuit, configured to generate a motion trajectory of the wireless charging device based on the power data of each of the at least two wireless charging coils, and identify a user instruction corresponding to the motion trajectory of the wireless charging device using a preset instruction identification model, the instruction identification model being a neural network model based on deep supervised learning; and
a cloud server, configured to control a smart home device based on the user instruction.

2. The system according to claim 1, wherein the power information collection circuit comprises a data acquisition sub-circuit; and
the data acquisition sub-circuit comprises a power sensor and a clock timer, and is configured to acquire the power data of each of the at least two wireless charging coils of the wireless charging coils of the multi-coil wireless charging circuit when the wireless charging device slides through the at least two wireless charging coils, and the power data of each of the at least two wireless charging coils comprises a coil number, current change amplitudes, and a current change time.

3. The system according to claim 2, wherein the power information collection circuit further comprises a data transmission sub-circuit; and the data transmission sub-circuit is connected in communication with the data processing circuit, and configured to transmit the power data of the at least two wireless charging coils to the data processing circuit.

4. The system according to claim 3, wherein the data processing circuit comprises a data processing sub-circuit and an instruction identification sub-circuit;
the data processing sub-circuit is electrically connected to the instruction identification sub-circuit; and the data processing sub-circuit is configured to generate the motion trajectory of the wireless charging device based on the power data of the at least two wireless charging coils, and transmit the motion trajectory to the instruction identification sub-circuit; and
the instruction identification sub-circuit is connected in communication with the cloud server, and is configured to load the preset instruction identification model to identify the user instruction corresponding to the motion trajectory, and transmit the user instruction to the cloud server.

5. A human-computer interaction method based on a wireless charging device using the system according to claim 1, the method comprising:
starting the multi-coil wireless charging circuit;
obtaining the power data of each of at least two wireless charging coils of the wireless charging coils of the multi-coil wireless charging circuit when the wireless charging device slides through the at least two wireless charging coils;
generating the motion trajectory of the wireless charging device based on the power data of the at least two wireless charging coils, and identifying the user instruction corresponding to the motion trajectory of the wireless charging device using the preset instruction identification model, the instruction identification model being the neural network model based on deep supervised learning; and
controlling the smart home device based on the user instruction.

6. The method according to claim 5, wherein the generating the motion trajectory of the wireless charging device based on the power data of the at least two wireless charging coils, specifically comprises:
step S1, obtaining the power data of the at least two wireless charging coils, and screening the power data of the at least two wireless charging coils to obtain a set of accurate power data;
step S2, obtaining a coil number of each power data of the set of accurate power data, and ordering obtained coil numbers in time sequence, to obtain a wireless charging coil number sequence; and
step S3, connecting wireless charging coils of the multi-coil wireless charging circuit corresponding to the obtained coil numbers based on the wireless charging coil number sequence, to obtain a wireless charging coil connecting line as the motion trajectory of the wireless charging device.

7. The method according to claim 6, wherein the screening the power data of the at least two wireless charging coils to obtain a set of accurate power data in the step S1, specifically comprises:
obtaining a maximum value of current change amplitudes and a current change time of the power data of each of the at least two wireless charging coils;
determining a power data screening value of the power data of each of the at least two wireless charging coils based on the maximum value of the current change amplitudes and the current change time; and
determining whether the power data screening value is within a set threshold range, if it is determined that the power data screening value is within the set threshold range, obtaining the power data as accurate power data of the set of accurate power data, otherwise not making the power data as accurate power data of the set of accurate power data.

8. The method according to claim 7, wherein the power data screening value is determined by a following formula:
Sᵢ=max[Eᵢ]*Tᵢ,
where Sᵢ represent the power data screening value of the i-th wireless charging coil of the wireless charging coils, max[Eᵢ] represents the maximum value of the current change amplitudes of the i-th wireless charging coil, and Tᵢ represents the current change time of the i-th wireless charging coil.
